(19) United States
(12) Patent Application Publication
(10) Pub. No.: US 2003/0012003 A1
(43) Pub. Date: Jan. 16, 2003

(54) Apparatus having an exchangeable housing part

(76) Inventors: Stefan Bischof, Nersingen (DE); Raimund Stetter-Alle, Ulm (DE)

Correspondence Address: BELL, BOYD & LLOYD, LLC, P. O. BOX 1135, CHICAGO, IL, 60690-1135, US

(21) Appl. No.: 10/182,452

(22) PCT Filed: Dec. 14, 2000
(86) PCT No.: PCT/DE00/04465

(30) Foreign Application Priority Data
Jan. 28, 2000 (DE) 100 03 699.6

(51) Int. Cl. H05K 5/00; H05K 5/06

(52) U.S. Cl. 361/730; 361/752

(57) ABSTRACT

The invention concerns an apparatus comprising a housing having an exchangeable housing part, a keyboard and a support located in the housing. Switching means assigned to the keys of the keyboard are disposed on said support. When the keys are pressed, said switching means trigger a corresponding switch impulse. Means for enhancing tactility of the corresponding keys are disposed between the keys of the keyboard and the switching means. The support is covered by a protective foil in the area of the exchangeable housing part, the means for enhancing tactility being integrated in said foil.

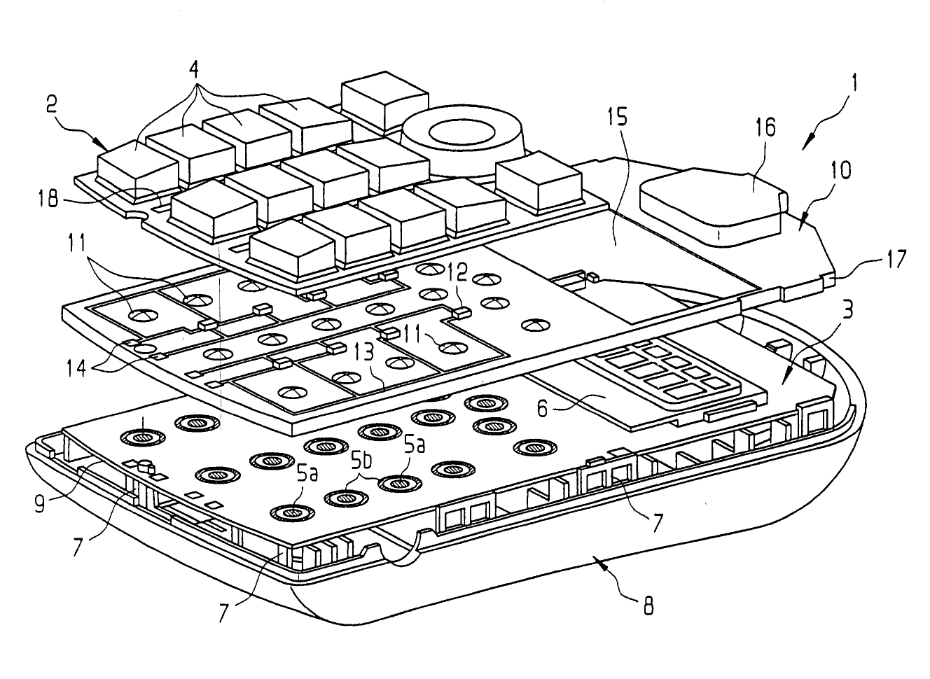

The invention relates to an apparatus having a housing with a housing part which can be removed by the user, having a keyboard and a support located in the housing with switching means that are arranged on said support, are associated with the keys of the keyboard and each trigger a switching pulse when the corresponding key is pressed.

In order to individualize apparatuses, in particular small mobile electronic apparatuses, more and more types with exchangeable housing parts are being offered by the manufacturers. This trend applies above all to mobile telephones and other communications terminals, for which reason the starting point in the following text will be the description of a mobile telephone or communications terminal. However, the invention is of course not restricted to such apparatuses but can also be used in other apparatuses, in particular the aforementioned small mobile apparatuses such as palmtops, organizers, etc.

In the case of mobile telephones, the exchangeable part is generally the so-called “upper shell” which surrounds the keyboard and possibly also the display. By exchanging this upper shell, in particular the coloration, to some extent also the design of the mobile telephone can easily be changed by the user so that he can give his mobile telephone an individual note or can even match the mobile telephone to clothing, possibly also to the location of his residence and the occasion on which the user takes the mobile telephone with him.

As a rule, apparatuses of this type have a keyboard in the form of a keyboard mat, which extends under the removable housing part and whose keys project outward through apertures in the removable housing part. In principle, however, it is also possible for the individual keys to be integrated directly in the removable housing part in such a manner that they can be moved. On a support located in the housing, for example the main circuit board of the mobile telephone, which usually also carries most of the other electronic components and/or conductor tracks, there are in each case switching means under the keys of the keyboard. As a rule, these are interrupted meandering conductor tracks or other two-part conductor track structures which are short-circuited when the corresponding key is pressed and as a result in each case trigger a switching pulse.

Since one of the substantial functions of the housing is to cover and protect the parts lying inside, in apparatuses which have housing parts that can be exchanged by the user, care must be taken that the parts lying inside cannot be damaged even when the housing part is changed. In particular, there is the risk that during the change damage will occur as a result of direct contact, that contaminants will get into the housing and, primarily, that sensitive components of the apparatus will be damaged or destroyed by electrostatic discharges.

It is known from practice to construct the mobile telephone in a double chassis design in order to protect the printed circuit board. In this case, underneath the exchangeable upper shell and the keyboard mat located underneath there is a solid subchassis made of plastic about 1.2 mm thick with a light conductor plate arranged under the keyboard mat in a corresponding recess. This light conductor plate is used to illuminate the keyboard. In the light conductor plate there are recesses, through which the plungers of the keys of the keyboard mat project and act on the circuit board with the switching means arranged thereon. Above the switching means and underneath the plungers of the keyboard plates there are in each case metal domes to increase the tactile nature. These metal domes are spherical domes which, under loading, twist through like so-called “frog clickers”, as a result of which the switching means on the support are short-circuited and therefore the switching pulse is triggered. In this case, the metal domes cohere in the form of a support mat in order to fix the metal domes in their respective position above the switching means and primarily for simpler assembly. This support mat in turn has corresponding apertures at specific positions, at which LEDs are fitted to the circuit board in order to illuminate the keyboard. The light from the LEDs passes through the aperture and over the light conductor plate to the keyboard mat and there forms the background lighting.

This double chassis design is extremely complicated and tolerable only in the case of higher-priced apparatuses.

It is an object of the present invention to provide a cost-effective and reliable alternative to this prior art.

This object is achieved in that, at least in the area of the removable housing part, the support is covered by a protective film, in which the means of increasing the tactile nature of the respective key are integrated.

This film covering provides reliable protection for the support and the circuit board against contact, ESD (Electrostatic Discharge), contaminants and so on. It is therefore possible to dispense with an expensive subchassis. As a result of the integration of the means of increasing the tactile nature, it is also possible to dispense with the additional support mat with the metal domes. Consequently, by means of the invention a plurality of previously necessary components are integrated into a single component which can be produced particularly cost-effectively. In addition to the savings in cost, the result in this case is also a smaller space requirement, which means that a smaller apparatus thickness can be achieved with such a protective film.

The means of increasing the tactile nature can be, for example, domes integrated into the protective film, in particular even the known metal domes. However, so-called “poly domes” are particularly preferably used. These are spherical domes which are molded into the film and which are provided with a conductive material, for example carbon, on the contact side, that is to say on the side facing the support. This conductive material can be applied inter alia by printing. However, other conventional processes for the application of conductive layers are also possible.

The protective film is preferably, at least in subareas, matched to the outer contours of the support and, if appropriate, of the components arranged thereon. In this way, for example, protection for the earpiece or the display can also be provided by the film at the same time.

The films can be shaped, for example, from polyester or polycarbonate using various fabrication methods, both cold forming and hot forming being possible. As a rule, the various film suppliers offer appropriate fabrication methods for their films, for example high-pressure forming. The films are preferably produced in the suitable shape with the integrated poly domes by means of simple thermoforming.

Depending on the apparatus, it is possible, for example as in the case of the apparatuses described at the beginning, for the removable housing part to be an upper shell which is put onto a lower shell of the apparatus. In this case, the protective film may possibly cover only the upper side of the support and, at the edge, be connected permanently or detachably to the lower shell, for example hooked or adhesively bonded to the lower shell. Alternatively, it is of course also possible for the film to be connected to the support itself, for example permanently adhesively bonded to the support or hooked to the support in any way.

In a further preferred exemplary embodiment, the underside of the support is also covered with a protective film. The two protective films are then connected to each other, for example welded or adhesively bonded, in such a way that an internal functional block completely protected against contact is produced.

Of course, the lower shell can also be configured so as to be removable, or the housing can be removed only in a subarea of the lower or upper shell.

In a particularly preferred embodiment, the protective film additionally has means of illuminating the keyboard. For example, these means of illuminating the keyboard can comprise individual light-emitting diodes which are arranged on the protective film and with which contact is made via conductor tracks. These conductor tracks on the protective film are then in turn connected at suitable points to conductor tracks on the support. Making contact between the conductor tracks for the light-emitting diodes on the protective film and the conductor tracks on the support can be carried out by means of various methods, for example by making direct contact by means of pad to pad, ZIF connectors (Zero Insertion Force), by means of a heat-seal process, by means of an anisotropic, conductive adhesive (ACF; Anisotropic Conductive Film) or the like. The conductor tracks can run both on the upper side of the protective film, pointing outward, and on the lower side, pointing toward the support, the plated-through contact to the outer side then in each case being carried out at the locations of the light-emitting diodes. In the case of such an embodiment, particularly good ESD protection is ensured. Furthermore, it is also possible for the conductor tracks to run on both sides of the protective film.

The integration of the means of eliminating the keyboard into the film has the advantage that the circuit board of the appliance itself, possibly apart from the display and from the earpiece, only has to be populated on one side. This provides considerable advantages in time and costs in fabrication. In addition, dispensing with a light conductor plate or the like contributes to a further reduction in the housing thickness.

During production, the protective film can be fabricated particularly beneficially independently of the circuit board and the appliance and, during final assembly, can simply be laid over the circuit board and integrated into the housing. Of course, depending on the fabrication, it is also possible during the production of the circuit board to cover the latter with a protective film and to supply the circuit board protected in this way as a preassembled subassembly and incorporate it into the housing during the final fabrication of the apparatuses.

The invention will be explained in more detail below using an exemplary embodiment and with reference to the attached drawing. The features illustrated may be essential to the invention not only in the combinations cited but also individually or in other combinations.

The single FIGURE shows a mobile telephone 1 with the upper shell removed (not illustrated) in an exploded illustration.

As viewed from bottom to top from the lower shell 8, this mobile telephone 1 is constructed as follows.

First of all, using appropriate fastening elements 7, a support 3 carrying the electronic components and the conductor tracks, that is to say the main circuit board 3, is plugged into the lower shell 8 and held there by the appropriate latching means. Apart from the display 6 and an earpiece (not illustrated) above the display 6, this main circuit board 3 carries all the electronic components and conductor tracks only on the underside pointing toward the lower shell 8, that is to say the main circuit board 3 is populated only on one side. In the keyboard area there are switching means 5a on the upper side of the main circuit board 3, in each case in the form of a two-part central pad 5a divided in a meandering or geometrically intersecting manner. A conductor track ring 5b arranged concentrically thereto serves for ESD protection. Both the parts of the central pad 5a at the center and the conductor ring 5b are plated through to the rear of the main circuit board 3. A switching pulse is triggered by means of a short circuit of the divided central pad 5a.

On the main circuit board 3 there is a thermoformed protective film 10, which is matched to the outer contours of the main circuit board 3 and, by means of an appropriate molding 16, to the earpiece located thereon. In the area of the display 6, this protective film also has a cutout 15, which is matched exactly to the contours of the display 6. Alternatively, it is of course also possible for a thin film layer shaped appropriately to extend over the display 6 here. The outer edge 17 of the protective film 10 extends all around the edge 9 of the main circuit board 3 and is therefore firmly hooked to the latter, by which means the protective film 10 is fixed to the main circuit board 3.

Poly domes 11 have been molded into the protective film 10 during the thermoforming. These are spherical domes which are provided with a carbon print on the inner side facing the circuit board. In the event of pressure from above on the poly domes 11, the latter twist through and, because of the contact with the conductive carbon material on the inner side of the dome, the switching means 5a on the main circuit board 3 are short-circuited.

In an exemplary embodiment that is not illustrated, metal domes are inserted into the spherical domes of the protective film 10 and, for example adhesively bonded to the protective film 10. If such metal domes are used, the conductor track rings around the central pads can also serve as part of the switching means. The central pads are then, for example, in one piece and the metal domes lie with their edge in each case on the conductor track ring. As a result, when they twist through, the respective conductor track ring is short-circuited with respect to the central pad. As compared with poly domes, metal domes have higher triggering forces, which achieves a particularly good tactile nature of the keyboard. However, the production costs are higher.

Furthermore, on the outer side of the protective film 10, there are light-emitting diodes 12 with associated series resistors (not illustrated) at various points. These light-emitting diodes 12 are connected in parallel with contact pads 14 at the ends via corresponding conductor tracks 13. These contact pads 14 are in turn connected via suitable plated-through holes to conductor tracks (not illustrated) on the circuit board 3, so that the light-emitting diodes 11 are supplied with operating voltage via these conductor tracks. Alternatively, these conductor tracks 13 can also be arranged on the underside of the protective film 10, pointing toward the circuit board 3. Through contact is then in each case made directly at the light-emitting diodes 12, so that there are no kinds of open contacts on the upper side of the protective film 10.

When assembled, the keyboard mat 2 with its individual keys 4 rests on this protective film 10. The upper shell (not illustrated) has apertures corresponding to the keys 4, through which the keys 4 project outward through the upper shell. When the keys 4 are operated, a pressure is exerted on the poly domes 11 of the protective film 10 located underneath, which then twist through as described and short-circuit the switching means 5a on the main circuit board 3. In the keyboard mat 2, at the appropriate positions between the keys 4, there are recesses for the light-emitting diodes 12 belonging to the protective film 10. The keyboard 2 is therefore illuminated by the light-emitting diodes 12.

In the present exemplary embodiment, the protective film 10 consists of a polyester or polycarbonate material and is produced in an extremely cost-effective manner by thermoforming in one operation. The thickness of the protective film is about 1/10 to 2/10 mm.

As a result of the protective film 10 according to the invention, there is the possibility of producing mobile telephones or other apparatuses even in the low-cost range, in which various housing parts can be exchanged simply by the user without there being the risk of damage to the apparatus. As a result of the integration of various functions such as illumination and improving the tactile nature directly into the protective film, an additional saving in costs and, above all, a lower space requirement are achieved. As a result of the further advantage, that populating a circuit board on one side is adequate, the result is additionally a high potential saving with respect to application costs.

1. An apparatus (1) having a housing with a housing part which can be removed by the user, having a keyboard (2) and a support (3) located in the housing with switching means (5a) which are arranged on said support, are associated with the keys (4) of the keyboard (2) and each trigger a switching pulse when the corresponding key (4) is pressed, and having means (11) respectively arranged between the keys (4) of the keyboard (2) and the switching means (5a) to increase the tactile nature of the respective key (4), characterized in that, at least in the area of the removable housing part, the support (3) is covered by a protective film (10), in which the means (11) of increasing the tactile nature are integrated, and which is shaped in such a way that it is matched to the outer contours of the support (3) and, if appropriate, of components (6) arranged thereon.

2. The apparatus as claimed in claim 1, characterized in that the means (11) of increasing the tactile nature have domes (11) molded into the protective film (10).

3. The apparatus as claimed in either of claims 1 and 2, characterized in that the protective film (10) is a thermoformed film (10).

4. The apparatus as claimed in one of claims 1 to 3, characterized in that the housing has a lower shell (8) and an upper shell that can be removed therefrom.

5. The apparatus as claimed in claim 4, characterized in that the protective film is connected to the lower shell.

6. The apparatus as claimed in one of the preceding claims, characterized in that the protective film (10) is connected to the support (3).

7. The apparatus as claimed in one of the preceding claims, characterized in that the protective film surrounds the support completely.

8. The apparatus as claimed in one of the preceding claims, characterized in that the protective film (10) has means (12, 13) of illuminating the keyboard (2).

9. The apparatus as claimed in claim 8, characterized in that the means (12, 13) of illuminating the keyboard (2) have light-emitting diodes (12) arranged on the protective film (10).

10. The apparatus as claimed in claim 9, characterized in that the protective film (10) has conductor tracks (13) to make contact with the light-emitting diodes (12).

11. The apparatus as claimed in claim 10, characterized in that the conductor tracks on the protective film are connected to conductor tracks on the support.

12. A protective film (10) for an apparatus (1), the apparatus [lacuna]
a housing with a housing part that can be removed by the user,
a keyboard (2) and a support (3) located in the housing with switching means (5a) that are arranged on said support (3), are associated with the keys (4) of the keyboard (2) and each trigger a switching pulse when the corresponding key (4) is pressed, and
means (11) respectively arranged between the keys (4) of the keyboard (2) and the switching means (5a) to increase the tactile nature of the respective key (4),
characterized
in that the protective film (10) covers the support (3), at least in the area of the removable housing part,
in that the means (11) of increasing the tactile nature are integrated into the protective film (10), and
in that the protective film (10) is shaped in such a way that it is matched to the outer contours of the support (3) and, if appropriate, of components (6) arranged thereon.

13. The protective film as claimed in claim 12, characterized in that the protective film (10) is made of polyester or polycarbonate or polyimide.

14. A circuit board (3) for an apparatus (1) as claimed in one of claims 1 to 11, characterized in that the circuit board (3) is at least partly covered by a protective film (10) as claimed in claim 12 or 13.
